(19) United States
(12) Patent Application Publication
(10) Pub. No.: US 2014/0340604 A1
(43) Pub. Date: Nov. 20, 2014

(54) Thin Film Transistor, Method for Manufacturing the Same, and LCD Device Having the Same

(71) Applicant: Shenzhen China Star Optoelectronics Technology Co. Ltd., Shenzhen, Guangdong (CN)

(72) Inventors: Cheng-Lung Chiang, Shenzhen City (CN); Po-Lin Chen, Shenzhen City (CN)

(73) Assignee: Shenzhen China Star Optoelectronics Technology Co., Ltd., Shenzhen, Guangdong (CN)

(21) Appl. No.: 13/981,333

(22) PCT Filed: Jun. 24, 2013
(86) PCT No.: PCT/CN2013/077754

§ 371 Date: Jul. 24, 2013

(30) Foreign Application Priority Data
May 16, 2013 (CN) 201310181621.X

(51) Int. Cl. G02F 1/1368; H01L 29/786; H01L 29/66; H01L 27/12

(52) U.S. Cl. CPC G02F 1/1368; H01L 27/1225; H01L 29/7869; H01L 29/66969
USPC 349/43; 257/43; 438/104

(57) ABSTRACT

The present invention provides a thin film transistor comprising at least a gate electrode formed on a substrate, and a gate insulating layer in contacting the gate electrode, and an oxide semiconductor layer deposited on the other side of the gate insulating layer. The concentration of hydrogen in the gate insulating layer has a gradient distribution, wherein the concentration of hydrogen adjacent the gate electrode is higher; and while the concentration of hydrogen adjacent the oxide semiconductor layer is lower. The present invention further provides a method for manufacturing a thin film transistor and an according thin-film-transistor liquid crystal display device. According to the embodiment of the present invention, the concentration of hydrogen in the gate insulating layer (especially the concentration of hydrogen adjacent the oxide semiconductor layer) will be effectively reduced, and thereby the deterioration of electrical properties of the thin film transistor resulted from the combination of the oxygen in the oxide semiconductor layer and the hydrogen in the gate insulating layer can be prevented.

The present patent application claims priority from Chinese Patent Application, No. 201310181621.X, entitled “Thin Film Transistor, Method for Manufacturing the Same, and LCD Device Having the Same”, and filed on May 16, 2013 in the China Patent Office, the entire contents of which are hereby incorporated herein by reference.

### FIELD OF THE INVENTION

The present invention relates to a technical field of a thin film transistor (TFT) technology, and more particularly to a thin film transistor, a method for manufacturing the same, and an LCD device having the same.

### BACKGROUND OF THE INVENTION

In recent years, there has been a technology has been developed to make the amorphous oxide semiconductor formed from indium (In), gallium (Ga), zinc (Zn), and oxygen (O) to a channel layer of a thin film transistor. However, an oxide semiconductor layer comprising such as zinc oxide is very sensitive to oxygen, and moisture etc. in the air. Accordingly, there is a potential risk to the oxide semiconductor resulted from the contact of oxygen and moisture such that the electrical characteristic of the semiconductor will be negatively changed. As a result, in order to ensure that a thin film transistor having stable characteristics, an oxide semiconductor layer must be separated and isolated from the air by creating a protective layer composed of insulating layers.

Such insulating protective layer can be formed by means of the plasma-enhanced chemical vapor deposition, sputtering deposition, or the like, but the hydrogen diffusion from the insulating protective layer may cause deterioration of characteristics of the thin film transistor.

Wherein a gate insulating layer (GI layer) is usually formed by means of the plasma-enhanced chemical vapor deposition (PEVCD), and the oxygen in an indium-gallium-zinc-oxide (IGZO) semiconductor layer may be combined with ambient hydrogen such that electrical properties and stability of components of the thin film transistor deteriorate. Generally, if the gate insulating layer is generated by silicon oxide, and then the concentration of hydrogen is about 5%; if the gate insulating layer is generated by silicon nitride, and then the concentration of hydrogen is up to 25%. In addition, the gate insulating layer is directly in contact with the oxide semiconductor layer, so that if the concentration of hydrogen in the gate insulating layer is too high, the oxide semiconductor layer will undoubtedly be combined with the hydrogen, and thereby electrical properties and stability of components of the thin film transistor will deteriorate. Thus, it is an important factor to consider during the fabricating process of an oxide thin film transistor that how to control the concentration of hydrogen in the gate insulating layer (especially the concentration of hydrogen adjacent the oxide semiconductor layer).

### SUMMARY OF THE INVENTION

It is an object of the present invention to provide a thin film transistor, a method for manufacturing the same, and an LCD device having the same. The concentration of hydrogen in a gate insulating layer can be lowered, and thereby the deterioration of electrical properties of a thin film transistor can be prevented.

In order to resolve the technical issue encountered by the prior art, the present invention provides a thin film transistor comprising at least a gate electrode formed on a substrate, and a gate insulating layer in contacting the gate electrode, and an oxide semiconductor layer deposited on the other side of the gate insulating layer. The concentration of hydrogen in the gate insulating layer has a gradient distribution, wherein the concentration of hydrogen adjacent the gate electrode is higher; and while the concentration of hydrogen adjacent the oxide semiconductor layer is lower.

Wherein the oxide semiconductor layer contains at least one of zinc oxide, tin oxide, indium oxide and gallium oxide.

Wherein the gate insulating layer is generated by any one of silicon oxide, silicon nitride, and silicon oxide nitride or the deposited layers of those chemicals thereof.

Wherein a source electrode layer, a drain electrode layer, and a protective layer are formed in sequence from external surface of the oxide semiconductor layer.

Wherein the concentration of hydrogen in the gate insulating layer adjacent the gate electrode is higher than 1E22/cm³.

Wherein the concentration of hydrogen in the gate insulating layer adjacent oxide semiconductor layer is lower than 1E22/cm³.

Accordingly, the present invention further provides a thin-film-transistor liquid crystal display device, wherein a thin film transistor is incorporated and which comprising at least a gate electrode formed on a substrate, and a gate insulating layer in contacting the gate electrode, and an oxide semiconductor layer deposited on the other side of the gate insulating layer; wherein the concentration of hydrogen in the gate insulating layer has a gradient distribution, wherein the concentration of hydrogen adjacent the gate electrode is higher; and while the concentration of hydrogen adjacent the oxide semiconductor layer is lower.

Wherein the oxide semiconductor layer contains at least one of zinc oxide, tin oxide, indium oxide and gallium oxide.

Wherein the gate insulating layer is generated by any one of silicon oxide, silicon nitride, and silicon oxide nitride or the deposited layers of those chemicals thereof.

Wherein a source electrode layer, a drain electrode layer, and a protective layer are formed in sequence from external surface of the oxide semiconductor layer.

Wherein the concentration of hydrogen in the gate insulating layer adjacent the gate electrode is higher than 1E22/cm³.

Wherein the concentration of hydrogen in the gate insulating layer adjacent oxide semiconductor layer is lower than 1E22/cm³.

Accordingly, the present invention further provides a method for manufacturing a thin film transistor including at least a step of dehydrogenating at high operating temperature performed after a step of the formation of the film of a gate insulating layer while before a step of the formation of an oxide semiconductor layer, such that the concentration of hydrogen in the gate insulating layer has a gradient distribution, wherein the concentration of hydrogen adjacent the gate electrode is higher; and wherein the concentration of hydrogen adjacent the oxide semiconductor layer is lower.

Wherein the processing condition for dehydrogenating at high operating temperature is conducted at 350° C. to 400° C. under vacuum environment for 0.5 to 1.5 hours.

Wherein the concentration of hydrogen in the gate insulating layer adjacent the gate electrode is higher than 1E22/cm³; and wherein the concentration of hydrogen in the gate insulating layer adjacent oxide semiconductor layer is lower than 1E22/cm³.

Advantages of practice of the present invention include the following. According to the embodiment of the present invention, dehydrogenating at high operating temperature is performed after the formation of the film of the gate insulating layer while before the formation of the oxide semiconductor layer, such that the concentration of hydrogen in the gate insulating layer has a gradient distribution, wherein the concentration of hydrogen adjacent the gate electrode is higher; and wherein the concentration of hydrogen adjacent the oxide semiconductor layer is lower. As a result, the concentration of hydrogen in the gate insulating layer (especially the concentration of hydrogen adjacent the oxide semiconductor layer) will be effectively reduced, and thereby the deterioration of electrical properties of the thin film transistor resulted from the combination of the oxygen in the oxide semiconductor layer and the hydrogen in the gate insulating layer can be prevented.

### BRIEF DESCRIPTION OF DRAWINGS

In order to give a better and thorough understanding to the whole and other intended purposes, features and advantages of the present invention or the technical solution of the prior art, detailed description will be given with respect to preferred embodiments provided and illustrated here below in accompanied drawings. Apparently, with the spirit of the embodiments disclosed, persons in the skilled in the art can readily come out with other modifications as well as improvements without undue experiment. In addition, other drawings can be readily achieved based on the disclosed drawings.

FIG. 1 is a cross-sectional and illustrational view of an embodiment of a thin film transistor made in accordance with the present invention;

FIG. 2 is a curve diagram of an embodiment of the concentration of hydrogen in the gate insulating layer made in accordance with the present invention; and

FIG. 3 is a flow-chart diagram illustrating the steps of an embodiment of a method for manufacturing a thin film transistor made in accordance with the present invention.

### DETAILED DESCRIPTION OF PREFERRED EMBODIMENTS

Detailed description will be given with respect to preferred embodiments provided and illustrated here below in accompanied drawings.

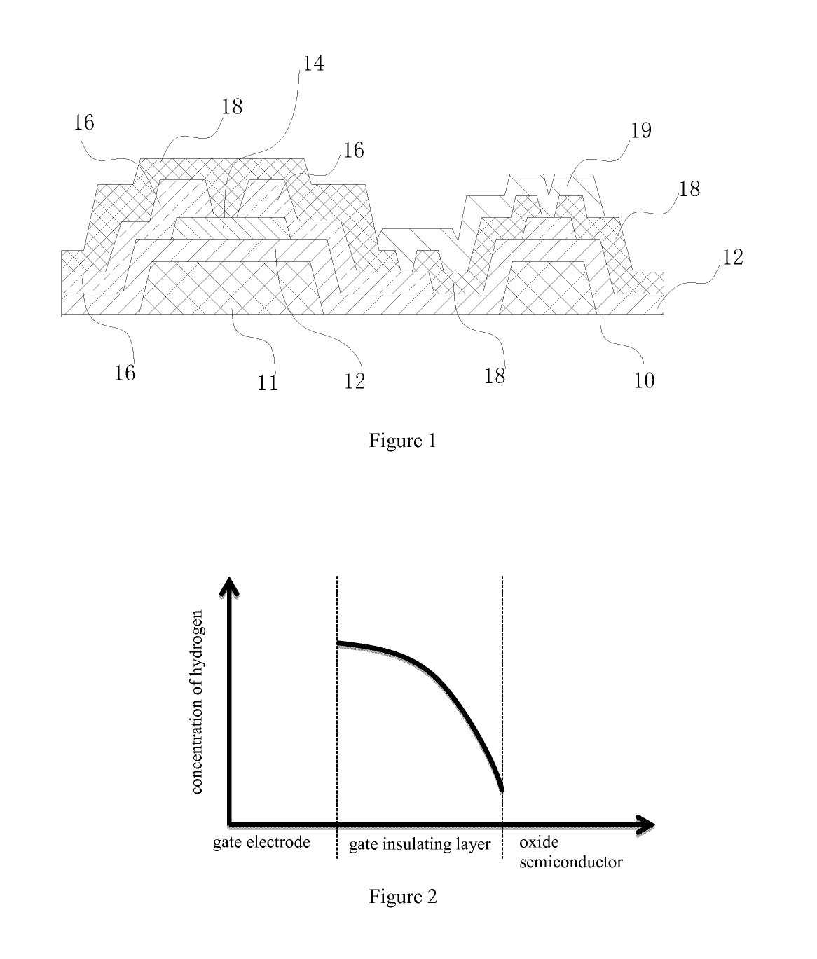

Referring to FIG. 1, which is a cross-sectional and illustrational view of an embodiment made in accordance with the present invention. Referring to FIG. 2 along with FIG. 1, as can be seen easily, a thin film transistor made in accordance with an embodiment of the present invention includes a substrate 10, a gate electrode formed on the substrate 10 and arranged in sequence, a gate insulating layer 12, an oxide semiconductor layer 14, a source/drain electrode layer 16, a protective layer 18, and a transparent conductive layer 19.

Wherein the gate electrode 11 is formed on the substrate 10, and one side of the gate insulating layer 12 contacts and covers the gate electrode 11, such that the gate electrode 11 is insulated from the outside. The oxide semiconductor layer 14 is deposited on the other side of the gate insulating layer 12; and the source electrode 16 and the drain electrode layer 16 contacts the oxide semiconductor layer 14 respectively. Outside the source electrode 16 and the drain electrode layer 16, the protective layer 18 is deposited; and the protective layer 18 is partially covered with the transparent conductive layer 19.

In the gate insulating layer 12, the concentration of hydrogen has a gradient distribution, wherein the concentration of hydrogen adjacent the gate electrode 11 is higher; and while the concentration of hydrogen adjacent the oxide semiconductor layer 14 is lower. A curve diagram of the concentration of hydrogen can be readily seen by referring to FIG. 2, and wherein the concentration of hydrogen in each part of the gate electrode 11 can be measured by Secondary Ion Mass Spectrometry. In one embodiment, the concentration of hydrogen in the gate insulating layer 12 adjacent the gate electrode 11 is higher than 1E22/cm³; and wherein the concentration of hydrogen in the gate insulating layer 12 adjacent oxide semiconductor layer 14 is lower than 1E22/cm³.

Substantially, the gate insulating layer 12 is generated by any one of silicon oxide, silicon nitride, and silicon oxide nitride or the deposited layers of those chemicals thereof. The oxide semiconductor layer 14 contains at least one of zinc oxide, tin oxide, indium oxide and gallium oxide.

According to the embodiment of the present invention, the concentration of hydrogen in the gate insulating layer 12 has a gradient distribution, wherein the concentration of hydrogen adjacent the gate electrode 11 is higher; and while the concentration of hydrogen adjacent the oxide semiconductor layer 14 is lower. As a result, the concentration of hydrogen in the gate insulating layer 12 (especially the concentration of hydrogen adjacent the oxide semiconductor layer 14) will be effectively reduced, and thereby the deterioration of electrical properties of the thin film transistor resulted from the combination of the oxygen in the oxide semiconductor layer 14 and the hydrogen in the gate insulating layer 12 can be prevented.

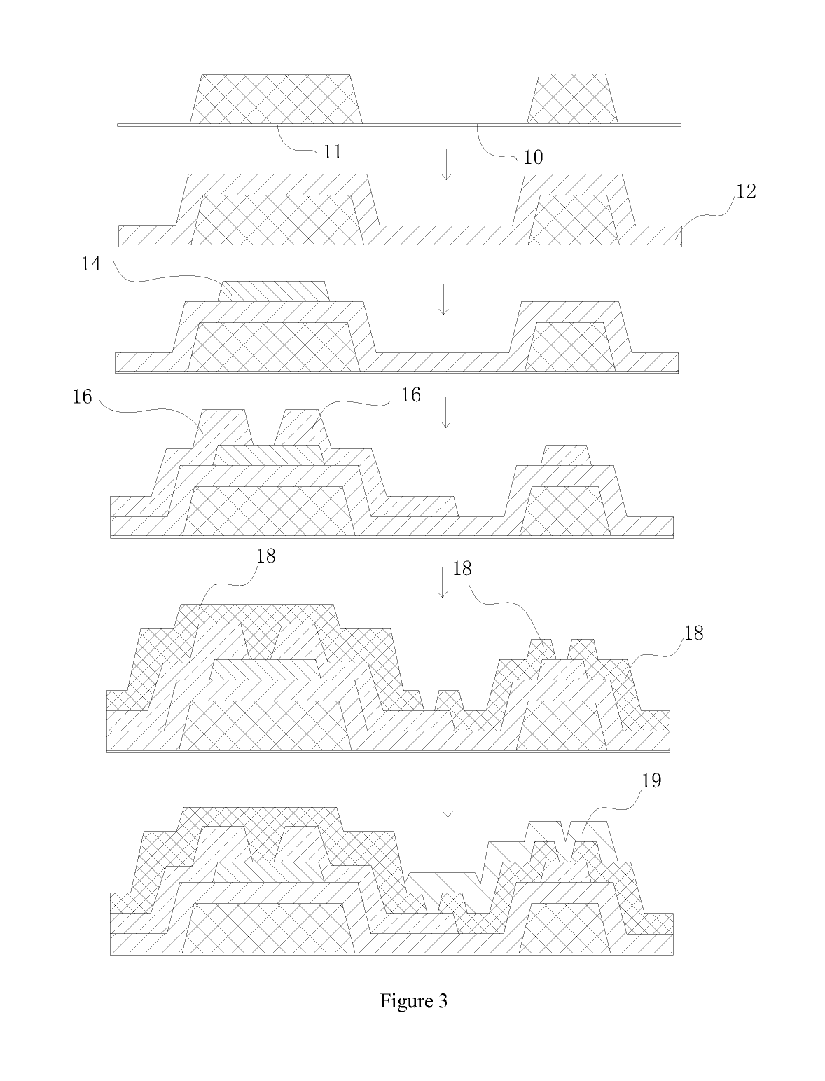

As shown in FIG. 3, a flow-chart diagram illustrating the steps of an embodiment of a method for manufacturing a thin film transistor made in accordance with the present invention. Further description of manufacturing a thin film transistor will be illustrated here below in the accompanied FIG. 3.

Firstly, on the substrate 10, the gate electrode 11 and the gate insulating layer 12 are formed, wherein the substrate 10 is a glass substrate, or a film or a sheet made of plastics such as polyethylene terephthalate (PET), polyethylene naphthalate (PEN), polyimide, or polycarbonate; and the substrate 10 may also be a stainless steel substrate coated with an insulating layer. The gate electrode 11 can be formed by means of the sputtering deposition, pulsed laser deposition (PLD), electron beam evaporation, chemical vapor deposition, etc. The gate insulating layer 12 is generated by any one of silicon oxide, silicon nitride, and silicon oxide nitride or the deposited layers of those chemicals thereof; and wherein the gate insulating layer 12 can be formed by means of the plasma-enhanced chemical vapor deposition (PEVCD). In other embodiments, the gate electrode 11 and the gate insulating layer 12 can be directly patterned by photolithography or/and etching. A step of dehydrogenating at high operating temperature is needed after a step of the formation of the film of a gate insulating layer 12, such that the concentration of hydrogen in the gate insulating layer has a gradient distribution, wherein the concentration of hydrogen adjacent the gate electrode is higher; and wherein the concentration of hydrogen adjacent the oxide semiconductor layer is lower. Substantially, the processing condition for dehydrogenating at high operating temperature is conducted at 350° C. to 400° C. under vacuum environment for 0.5 to 1.5 hours (i.e. 1 hour). In one embodiment, after the step of dehydrogenating, the concentration of hydrogen in the gate insulating layer adjacent the gate electrode is higher than 1E22/cm³, and the concentration of hydrogen in the gate insulating layer 12 adjacent the oxide semiconductor layer 14 is lower than 1E22/cm³.

Furthermore, the oxide semiconductor layer 14 is formed, for example, by using a DC sputtering apparatus, and wherein the oxide semiconductor layer 14 contains at least one of zinc oxide, tin oxide, indium oxide and gallium oxide.

Then the source/drain electrode layer 16 is formed on the oxide semiconductor layer 14, which can be patterned by photolithography or/and etching; then the protective layer 18 is deposited on the source/drain electrode layer 16, and the protective layer 18 is partially covered with the transparent conductive layer 19; as an alternative step, finally annealing at a specific temperature (i.e. 250° C.) in air for certain time (i.e. 1 hour) by using a furnace so as to remove lesions generated by etching. Thus, an oxide semiconductor thin film transistor is formed.

According to another aspect of the present invention, the present invention further provides a thin-film-transistor liquid crystal display device, has incorporated the thin film transistor as described above in the accompanied FIG. 1 to FIG. 3. More details can be readily understood by referring to the above description and no additional description is given here below.

Advantages of practice of the present invention include the following. According to the embodiment of the present invention, dehydrogenating at high operating temperature is performed after the formation of the film of the gate insulating layer while before the formation of the oxide semiconductor layer, such that the concentration of hydrogen in the gate insulating layer has a gradient distribution, wherein the concentration of hydrogen adjacent the gate electrode is higher; and wherein the concentration of hydrogen adjacent the oxide semiconductor layer is lower. As a result, the concentration of hydrogen in the gate insulating layer (especially the concentration of hydrogen adjacent the oxide semiconductor layer) will be effectively reduced, and thereby the deterioration of electrical properties of the thin film transistor resulted from the combination of the oxygen in the oxide semiconductor layer and the hydrogen in the gate insulating layer can be prevented.

Preferred embodiments of the present invention have been described, but not intending to impose any unduly constraint to the appended claims. Any modification of equivalent structure or equivalent process made according to the disclosure and drawings of the present invention is considered encompassed in the scope of protection defined by the claims of the present invention.

1. A thin film transistor comprising at least a gate electrode formed on a substrate, and a gate insulating layer in contacting the gate electrode, and an oxide semiconductor layer deposited on the other side of the gate insulating layer;
wherein the concentration of hydrogen in the gate insulating layer has a gradient distribution, wherein the concentration of hydrogen adjacent the gate electrode is higher; and
while the concentration of hydrogen adjacent the oxide semiconductor layer is lower.

2. The thin film transistor as recited in claim 1, wherein the oxide semiconductor layer contains at least one of zinc oxide, tin oxide, indium oxide and gallium oxide.

3. The thin film transistor as recited in claim 2, wherein the gate insulating layer is generated by any one of silicon oxide, silicon nitride, and silicon oxide nitride or the deposited layers of those chemicals thereof.

4. The thin film transistor as recited in claim 3, wherein a source electrode layer, a drain electrode layer, and a protective layer are formed in sequence from external surface of the oxide semiconductor layer.

5. The thin film transistor as recited in claim 4, wherein the concentration of hydrogen in the gate insulating layer adjacent the gate electrode is higher than 1E22/cm³.

6. The thin film transistor as recited in claim 5, wherein the concentration of hydrogen in the gate insulating layer adjacent oxide semiconductor layer is lower than 1E22/cm³.

7. A thin-film-transistor liquid crystal display device, wherein a thin film transistor is incorporated and which comprising at least a gate electrode formed on a substrate, and a gate insulating layer in contacting the gate electrode, and an oxide semiconductor layer deposited on the other side of the gate insulating layer;
wherein the concentration of hydrogen in the gate insulating layer has a gradient distribution, wherein the concentration of hydrogen adjacent the gate electrode is higher; and
while the concentration of hydrogen adjacent the oxide semiconductor layer is lower.

8. The thin-film-transistor liquid crystal display device as recited in claim 7, wherein the oxide semiconductor layer contains at least one of zinc oxide, tin oxide, indium oxide and gallium oxide.

9. The thin-film-transistor liquid crystal display device as recited in claim 8, wherein the gate insulating layer is generated by any one of silicon oxide, silicon nitride, and silicon oxide nitride or the deposited layers of those chemicals thereof.

10. The thin-film-transistor liquid crystal display device as recited in claim 9, wherein a source electrode layer, a drain electrode layer, and a protective layer are formed in sequence from external surface of the oxide semiconductor layer.

11. The thin-film-transistor liquid crystal display device as recited in claim 10, wherein the concentration of hydrogen in the gate insulating layer adjacent the gate electrode is higher than 1E22/cm³.

12. The thin-film-transistor liquid crystal display device as recited in claim 11, wherein the concentration of hydrogen in the gate insulating layer adjacent oxide semiconductor layer is lower than 1E22/cm³.

13. A method for manufacturing a thin film transistor including at least a step of dehydrogenating at high operating temperature performed after a step of the formation of the film of a gate insulating layer while before a step of the formation of an oxide semiconductor layer, such that the concentration of hydrogen in the gate insulating layer has a gradient distribution, wherein the concentration of hydrogen adjacent the gate electrode is higher; and wherein the concentration of hydrogen adjacent the oxide semiconductor layer is lower.

14. The method for manufacturing a thin film transistor as recited in claim 13, wherein the processing condition for dehydrogenating at high operating temperature is conducted at 350° C. to 400° C. under vacuum environment for 0.5 to 1.5 hours.

15. The method for manufacturing a thin film transistor as recited in claim 14, wherein the concentration of hydrogen in the gate insulating layer adjacent the gate electrode is higher than 1E22/cm³; and wherein the concentration of hydrogen in the gate insulating layer adjacent oxide semiconductor layer is lower than 1E22/cm³.
